(19) United States
(12) Patent Application Publication
(10) Pub. No.: US 2021/0161025 A1
(43) Pub. Date: May 27, 2021

(54) ASSOCIATING CHASSIS MANAGEMENT CONTROLLERS WITH RACK SUPPORT UNITS

(71) Applicant: HEWLETT PACKARD ENTERPRISE DEVELOPMENT LP, Houston, TX (US)

(72) Inventor: Charles W. Cochran, Houston, TX (US)

(21) Appl. No.: 16/692,854

(22) Filed: Nov. 22, 2019

(51) Int. Cl. H05K 7/14; H05K 7/20; H04L 29/12; H04Q 11/00

(52) U.S. Cl. CPC H05K 7/1445; H05K 7/1491; H05K 7/1489; H04Q 11/0005; H05K 7/20836; H04L 61/2015; H05K 7/1492

(57) ABSTRACT

A technique includes receiving, from a primary chassis management controller, data representing an identifier for a support unit for a computer system rack. The presence of the support unit is detected by the primary chassis management controller, the primary chassis management controller is one of a plurality of chassis management controllers that are installed in the rack; and the plurality of chassis management controllers includes a plurality of secondary chassis management controllers. The technique includes accessing network switch forwarding table data; and based on the network switch forwarding table data and the identifier for the support unit, identifying a given secondary chassis management controller to which the support unit is connected by a network cable.

### BACKGROUND

A computer system may have a number of computers and computer-related components that are electrically connected together. One type of computer system is a rack-based system in which modular computer units (or “chassis units”) are mounted to a frame, or rack. A given chassis unit may have a set of processing nodes; networking and storage components; and the chassis unit may also have a chassis management controller, which allows the components to be remotely monitored and managed.

### BRIEF DESCRIPTION OF THE DRAWINGS

FIG. 1 is a schematic diagram of a computer network according to an example implementation.

FIG. 2 is an illustration of a rack-based computer system of the computer network of FIG. 1 according to an example implementation.

FIG. 3 is a signal flow diagram depicting a process to automatically discover information about a rack-based computer system including the discovery of associations between chassis management controllers and rack support units using forwarding table information stored in network switches of the chassis management controllers according to an example implementation.

FIG. 4 is a signal flow diagram depicting a process to automatically discover information about a rack-based computer system including the discovery of associations between chassis management controllers and rack support units using forwarding table information stored in a top-of-the-rack (ToR) network switch according to an example implementation.

FIG. 5 is a flow diagram depicting a technique to identify network cabling and/or configuration problems associated with a rack-based computer system according to an example implementation.

FIG. 6 is a flow diagram depicting a technique to identify a chassis management controller connected to a rack support unit according to an example implementation.

FIG. 7 is an illustration of machine executable instructions that are stored on a non-transitory storage medium and which are executable by a machine to cause the machine to identify an issue associated with a rack-based computer system according to an example implementation.

FIG. 8 is a schematic diagram of an apparatus to associate a chassis management controller with a support unit based on a media access control (MAC) address of the support unit and network switch-based forwarding table data according to an example implementation.

### DETAILED DESCRIPTION

A rack-based computer system that may have modular units (called “chassis units” herein) that are mounted to a frame, or rack. The chassis units may be mounted to frame members of the rack and may be located in an interior space that is defined by the frame members. A given chassis unit may contain any of a number of different computer components and serve any of a number of different purposes. As examples, a given chassis unit be a compute server; an application server; a storage server; an edge processing server; a blade enclosure; an enclosure containing tray-mounted server nodes; and so forth.

The chassis unit may contain a chassis management controller, which is connected to a network to allow remote monitoring and management of components of the chassis unit. As used herein, a “chassis management controller” is a specialized service processor that, in general, manages and reports on the operation of a computer environment (such as the chassis unit), which may have multiple servers, storage devices, and networking devices. The chassis management controller may operate independently of the operating system of the chassis unit. The chassis management controller may be located on the motherboard or main circuit board of the server or other device to be monitored. The fact that a chassis management controller is mounted on a motherboard of the managed server/hardware or otherwise connected or attached to the managed server/hardware does not prevent the chassis management controller from being considered “separate” from the server/hardware. As used herein, a chassis management controller has management capabilities for sub-systems of a computing device, and is separate from a processing resource that executes an operating system of a computing device. The chassis management controller is separate from a processor, such as a central processing unit, which executes a high level operating system or hypervisor on a system.

The chassis units may have associated relative locations within the rack, with the locations corresponding to chassis location identifications (IDs), or “chassis IDs.” A given chassis unit may learn its chassis ID through a chassis unit location indicator of the unit. The chassis location unit indicator may be an electromechanical device (e.g., a dial indicator) with a settable position-based indicator (e.g., a dial rotated to point to a particular number) to identify the chassis ID; and the device outputs an electrical indication (e.g., a digital value) that represents the chassis ID. For example, for a vertically-oriented rack in which the chassis units are arranged in a vertical stack, the lowermost chassis unit may be “chassis unit 1” having a chassis ID of “1” (as set by a dial on the unit pointing to “1”, for example); the chassis unit directly above chassis unit 1 may be “chassis unit 2” having a chassis ID of “2”; and so forth.

The chassis units may also have rack indicators (e.g., dial indicators), which are set to indicator a rack ID for the units. All chassis units of the same rack have the same rack ID; and this information may be used to associate chassis units with their racks in a network that contains multiple rack-based computer systems.

In addition to the chassis units and rack, a rack-based computer system may contain one or multiple support units (called “rack support units” herein), which may be disposed on the outside of the rack (i.e., not disposed in the interior space where the chassis units are mounted) and provide one or multiple support functions (e.g., provide power distribution and/or thermal cooling) for the chassis units. For example, a rack-based computer system may have one or multiple power distribution units (PDUs). A PDU may, for example, contain circuitry to receive three phase A/C power and convert the three phase A/C power to single phase AC power to the chassis units, which convert the AC power into DC power (via AC-to-DC power supplies or high power DC rectifiers) and distribute the DC power to the chassis unit backplane. In accordance with further example implementations, a PDU may convert AC power into DC power, condition DC power, distributed DC power, and so forth. As a specific example of a rack support unit, a given rack-based computer system may contain a pair of PDUs, where each PDU is mounted on a different side of the rack and extends in the direction along which the chassis units are mounted. The PDU may be connected by a network cable (e.g., an Ethernet cable) to the network port (e.g., an Ethernet port) of a given chassis management controller of the system for purposes of allowing remote monitoring and management of the PDU. In this manner, the network connection allows remote sensing of power demands, controlling the enablement of power conditioning circuitry per chassis unit, controlling whether a chassis unit is powered up or down, and so forth.

As another example of a rack support unit, a rack-based computer system may have a cooling distribution unit (CDU), which is a heat exchanger that removes waste heat from the computer system so that the components of the system remain within an acceptable thermal operating range. As an example, a CDU may be a liquid-based cooling system that includes a secondary cooling loop to circulate and receive a liquid coolant that is circulated near heat dissipating components of the chassis units and the heat sinks mounted to these components. The CDU may contain one or multiple heat exchangers to remove thermal energy from the liquid coolant of the secondary cooling loop and transfer this energy to a primary cooling loop. As another example, the CDU may be an air-to-coolant heat exchanging unit. Regardless of whether the CDU is a liquid-based cooling system or an air and liquid-based cooling system, the CDU may be connected by a network cable (e.g., an Ethernet cable) to a network port (e.g., an Ethernet port) of a given chassis management controller for purposes of allowing remote monitoring and management of the CDU (e.g., for purposes of sensing thermal conditions, controlling the circulating rate of the coolant, controlling fan speed, and so forth).

The rack-based computer system may be managed by a server, called a “rack manager” herein, which communicates with the chassis management controllers of the chassis units. In general, a chassis management controller allows the rack manager to gather information about and control an associated chassis unit of the rack-based computer system. The rack manager may manage multiple rack-based computer systems.

A given rack contains multiple chassis management controllers (one for each chassis unit). In accordance with example implementations, one of the chassis management controllers (called the “primary chassis management controller” herein) may be designated to be the master, or primary, chassis management controller for the rack; and the other chassis management controllers are designated as “secondary chassis management controllers.”

The primary chassis management controller may perform the function of discovering the presence of and information about the rack support units of the rack-based computer system, such as detecting the presence of CDUs and/or PDUs and retrieving information about these units. In this manner, the primary chassis management controller may, via cabling connections (described further herein) detect the presence of an installed rack support unit, communicate with the rack support unit to acquire data representing information about the rack support unit (called “field replaceable unit data” or “FRU data” herein) and communicate data to the rack manager representing the information about the rack support unit. As an example, the FRU data may be data representing an address (e.g., a media access control (MAC) address) of the support unit as well as possible other information about the support unit, such as a part number, hardware version number, firmware version number, serial number, and so forth.

A given rack-based computer system may be rather complex, in that the system may be formed from many different possible combinations of chassis units and support units. Moreover, there may be a considerable number of cable-based connections between these components, such as network cabling (e.g., Ethernet cabling), serial port cabling (e.g., RS232 cabling) and multi-pin cabling. The “multi-pin cabling” refers to cabling that has multiple conductors communicate signals, such as, for example, network signals, serial signals, presence signals, general purpose input/output (GPIO) signals, and so forth. For example implementations that are described herein, display port (DP) cables are used for the multi-pin cabling, although other types of cable may be used for the multi-pin cabling, in accordance with further implementations.

As described further herein, the cable connections may be subject to predefined “best practices” connection rules. As examples, the rules may specify that certain a rack support unit is to be connected (via a network cable, such as an Ethernet cable) to the network port of a chassis management controller having a specific chassis ID; assign serial port connectors of the primary chassis management controller to specific corresponding rack support units; assign display port connectors of the primary chassis management controller as hub port connectors for a star network, which connect to specific corresponding second chassis management controllers; designate a specific secondary chassis management controller display port as being a spoke connector of the start network; and so forth.

Connecting the cabling among the components of the rack-based computer system is prone to human error. Moreover, other aspects of setting up a rack-based computer system may be subject to human error. As examples, a chassis ID dial indicator may incorrectly be set such that there are two chassis units that are assigned chassis ID 2; the lowermost chassis unit on a vertical rack may not be assigned chassis ID 1 by its dial indicator; the rack indicator dial on a chassis unit may incorrectly associate the chassis unit with the wrong rack ID; and so forth.

In accordance with example implementations, a rack manager, performs an automatic discovery process to learn information about a rack-based computer system, and from this information, the rack manager may automatically identify problems with the setup of the rack-based computer system, such as problems with network cabling and/or configuration problems. The information learned through the automatic discovery may include, for example, information about the chassis units and chassis management controllers installed in the rack; the identification of the primary chassis management controller; the locations of the chassis management controllers in the rack; chassis IDs of the chassis management controllers; internet protocol (IP) addresses of the chassis management controllers; the presence of support units, such as PDUs and a CDU; the IP addresses of the support units; FRU information about the support units; and so forth.

In accordance with example implementations that are described herein, through the automatic discovery process, the rack manager learns information about network connections between the support units and the chassis management controllers. For example, the connection rules for the rack-based computer system may specific that the network port of a certain PDU A is supposed to be connected to the network port of a network switch that is disposed in the secondary chassis management controller having chassis ID 2. Through the automatic discovery process, the rack manager learns network connection mappings, or associations, being the rack support units and the chassis management controllers so that, using the results of the network connection associations, the rack manager may determine whether, for example, the network port of PDU A is connected to the network switch of the secondary chassis management controller having chassis ID 2.

More specifically, in accordance with example implementations, each chassis management controller includes a layer two network switch, and the network switch has different network ports. One of these network ports may be connected to a top-of-the-rack (ToR) network switch for the rack, and the other network ports may be potentially connected, via network cabling (e.g., Ethernet cabling), to other components, such as a rack support unit. The network switch populates a level two table, called a “forwarding table,” with a mapping between component identifiers (e.g., hardware addresses, such as MAC addresses) and the ports of the switch that are connected to components having these identifiers.

The network switch may learn this information and populate this table based on, for example, communications with the components that are connected to the ports. For example, a PDU may be connected by network cabling to a port of a given network switch of a given secondary chassis management controller. The PDU may issue a network frame (e.g., a frame corresponding to a Dynamic Host Control Protocol (DHCP) request or a frame corresponding to an Address Resolution Protocol (ARP) request) that contains a source address, which is the MAC address of the PDU. From this frame, the network learns, for example, that a component having the MAC address is connected to the port and updates the forwarding table accordingly.

In accordance with example implementations, the remote rack manager, as part of the automatic discovery process, requests the forwarding tables of the network switches of the chassis management controllers. A forwarding table for a given chassis management controller reveals the MAC addresses of the devices that are connected to the network switch of the chassis management controller and thus, reveals the support unit(s) that are connected to the chassis management controller by network cabling. In accordance with example implementations, the rack manager learns the chassis IDs and MAC addresses of all of the chassis management controllers from the controllers' DHCP requests; and the rack manager learns the MAC addresses of the support units from communications with the primary chassis management controller. Therefore, from the forwarding tables and the MAC addresses of the rack support units, the rack manager may associate specific chassis management controllers to specific rack support units; and the rack manager may use these associations to identify network cabling and/or configuration problems.

In accordance with further example implementations, the rack manager may discover the chassis management controller network to rack support unit associations using forwarding table information derived from one or multiple other network switches (i.e., from switch(es) other than the network switches of the chassis management controllers). For example, in accordance with further example implementations, the rack manager may request the forwarding table from the ToR network switch for the rack-based computer system. The ToR network switch is a level two network switch, which has ports that are connected to the network ports of the chassis management controllers by network cabling. The rack manager uses its knowledge of the MAC addresses of the chassis management controllers and rack support units, in conjunction with the forwarding table mapping from the ToR network switch, to determine associations between the chassis management controllers and the rack support units. For example, from the forwarding table provided by the ToR network switch, the rack manager may learn, for example, that a given port of the ToR network switch is mapped to the MAC address of a given support unit and also mapped to the MAC address of a given chassis management controller.

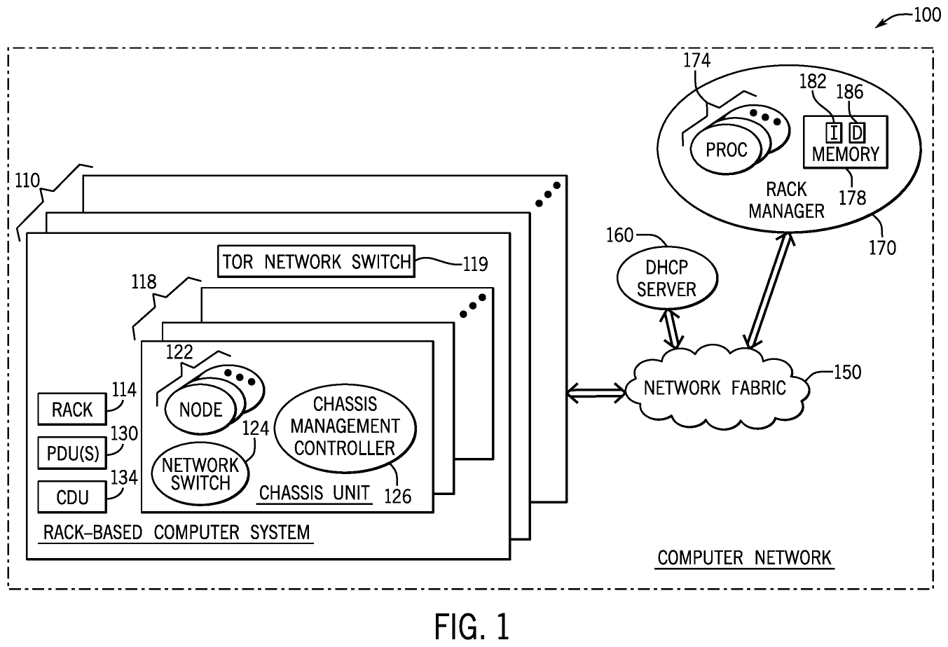

Referring to FIG. 1, as a more specific example, in accordance with some implementations, a computer network 100 includes multiple rack-based computer systems 110 and a rack manager 170. The rack manager 170 is connected to the rack-based computer systems 110 over network fabric 150; and, as described herein, in accordance with example implementations, the rack manager 170 is constructed to perform an automated discovery process for each rack-based computer system 110 for purposes of gathering information about the system 110 and identifying potential configuration and/or network cabling problems.

In general, a given rack-based computer system 110 may include multiple cartridges, or chassis units 118, where each chassis unit 118 may be mounted to a frame (i.e., a chassis), housed in an enclosure and include computer-related components, such as one or multiple processing nodes 122, a network switch 124 and an associated chassis management controller 126. In addition to the chassis units 118, the rack-based computer system 110 may include other components, such as one or multiple rack support units (e.g., one or multiple PDUs 130, and/or a CDU 134), a ToR network switch 119, and so forth.

As part of an automatic discovery process, the rack manager 170 may discover a particular chassis management controller 126 in response to the chassis management controller 126 providing a dynamic host control protocol (DHCP) request for an IP address. In this manner, the DHCP request is a broadcast domain request, which is not only seen by a DHCP server 160 that is coupled to the network fabric 150 but may also be observed by the rack manager 170. In accordance with example implementations, the DHCP request contains information identifying the sender of the DHCP request; and as such, the DHCP request from the chassis management controller 126 may contain a MAC address, rack ID identifier and a chassis ID of the controller 126. Therefore, by extracting this information from the DHCP request, the rack manager 170 may be able to associate a given chassis management controller 126 with a rack-based computer system 110 and a particular chassis location within that system 110; and the rack manager 170 may identify the primary chassis management controller 126 (e.g., the controller 126 having a chassis ID 1).

In accordance with example implementations the rack ID, chassis ID and MAC address of the sending device are communicated via the DHCP request using DHCP vendor specific option 0x43, which defines 64 octets beginning at octet offset 278. Sixty-four octets are allowed beginning at octet offset 278 for options, and the format is: code, length, data item. The MAC address of the sending device is at offsets 6 and 70. The sixty-four octets beginning at octet offset 278 may has the following packet format, in accordance with example implementations. The first four octets are a magic cookie; the next octet is vendor specific information code; the next octet is the length; the next two octets are code 2 and length; the next three octets identify the manufacturer; the next two octets are code 3 and length; the next two octets are the version (00 to FF); the next two octets are code 4 and length; the next eight octets are the rack and chassis IDs (in the format of “RnnnnCnn,” where “Rnnnn” represents a rack ID number between 0000 and 9999, and “Cnn” represents a chassis ID number between 00 and 99); and the last 39 octets contain padding data.

As described further therein, the PDUs 130 and CDUs 134 may also issue DHCP requests for purposes of acquiring IP addresses. These DHCP requests pass through the network switches (such as network switches 119 and 124) of the rack-based computer system 110 containing the PDUs 130 and CDUs 134, and accordingly, the network switches of the rack-based computer system 110 update their forwarding tables to map network switch ports to the MAC addresses of these components. As described herein, the rack manager 170 acquires information about the rack support units of a given rack-based computer system 110 from the primary chassis management controllers 126, including the MAC addresses of the support units. Using these MAC addresses, the rack manager 170 may acquire forwarding table information from the network switches of the rack-based computer system 110 for purposes of associating the chassis management controllers 126 with the support units that are connected by network cabling to the controllers 126.

As depicted in FIG. 1, in accordance with some implementations, the rack manager 170 may include one or multiple processors 174, such as one or multiple central processing units (CPUs), one or multiple CPU processing cores, and so forth. Moreover, the processor(s) 174 may execute program instructions 182 that are stored in a memory 178 for purposes of performing one or more of the techniques that are described herein. The memory 178 may also store data 186 that may be, for example, data representing MAC addresses for support units, MAC addresses for chassis management controllers; rack and chassis ID associations for rack-based components, such as support units, chassis management controllers, and so forth; network switch forwarding table data provided by network switches; cabling connection rules for the rack-based computer system; determined associations between chassis management controllers and rack support units; identified network cabling errors; identified configuration problems; and so forth.

In accordance with example implementations, the memory 178 is a non-transitory memory that may be formed from such memory devices as magnetic storage devices, semiconductor devices, memristors, phase change memory devices, a combination of one or more of the foregoing memory devices, and so forth.

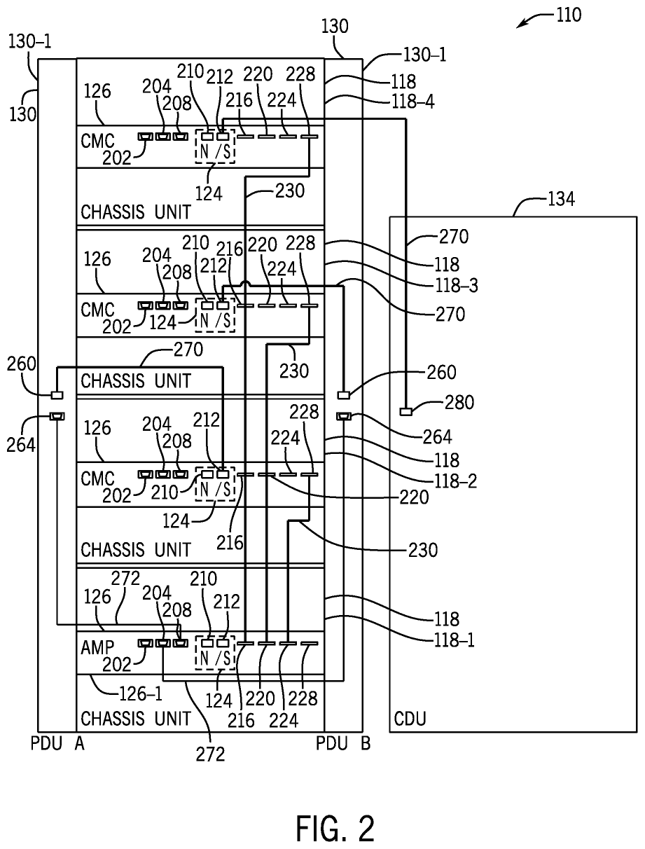

FIG. 2 illustrates a rack-based computer system 110 in accordance with example implementations. It is noted that for the example implementation depicted in FIG. 2, the ToR switch 119, as well as the network cabling connections to the ToR switch 119, are not depicted. Moreover, for this example implementation, the rack-based computer system 110 includes four chassis units 118 (specifically identified as chassis units 118-1, 118-2, 118-3 and 118-4 in FIG. 2) that are installed in a vertical orientation on a rack and have corresponding vertical locations in the rack. For the example implementation that is depicted in FIG. 2, the chassis unit 118-1 is the lowermost unit; the chassis unit 118-2 is immediately above the chassis unit 118-1; the chassis unit 118-3 is immediately above the chassis unit 118-2; and the chassis unit 118-4 is the top unit. The chassis management controllers 126 have respective chassis IDs, which should correspond to their respective rack locations.

The chassis IDs may be set by electromechanical indicators, for example (e.g., dial indicators) located on the chassis management controllers 126. As an example, chassis management controller 126 of the chassis unit 118-1 corresponds to chassis ID 1; the chassis management controller 126 of the chassis unit 118-2 corresponds to chassis ID 2; and so forth. In accordance with example implementations, the chassis management controller 126 having chassis ID 1 is the primary chassis management controller 126, with the other chassis management controllers 126 being the secondary chassis management controllers for the rack-based computer system 110.

In accordance with example implementations, the chassis management controller 126 has a number of ports, such as example port connectors 202, 204, 208, 210, 212, 216, 220, 224 and 228 that are depicted in FIG. 2, which connect the chassis management controller 126 to various network, DP, and serial communication cables. The connection of these cables may be subject to predefined connection rules. For example, the port connectors 216, 220, 224 and 228 are DP port connectors, and the primary chassis management controller 126 (i.e., the controller 126 of chassis unit 118-1) is be connected by DP cabling 230 in a star network to the secondary chassis management controllers 126, such that the primary chassis management controller 126 is the hub of the network. The connection rules specify which DP port connector of the primary chassis management controller 126 is connected to which secondary chassis management controller 126; and the primary chassis management controller 126 uses the defined connections to associate its DP ports with correspond chassis IDs. For example, the cabling connection rules may specify that the DP port connector 216 of the primary chassis management controller 126 is connected to the DP port connector 228 of the secondary chassis management controller 126 corresponding to chassis ID 4; the DP port connector 220 of the primary chassis management controller 126 is connected to the DP port connector 228 of the secondary chassis management controller 126 corresponding to chassis ID 3; and the port connector 224 of the primary chassis management controller 126 is connected to the port connector 228 of the secondary chassis management controller 126 corresponding to chassis ID 2.

Moreover, the cable connection rules may specify how cabling connections are to be made between rack support units and the chassis management controllers 126. For the example implementation that is depicted in FIG. 2, the rack-based computer system 110 includes two PDUs: a first PDU 130-1 (also called “PDU A” herein) connected to the left side of the rack, and a second PDU 130-2 (also called “PDU B” herein) connected to the right side of the rack. For the PDU A, the cable connection rules may specify how the PDUs and primary chassis management controller 126 is connected by serial port cabling 272. It is noted that the serial specify that port connector 208, a serial communication port connector (e.g., an RS232 connector), of the primary chassis management controller 126 is to be connected to a serial communication port connector 264 of PDU A; and the cabling connection rules may specify that port connector 204, another serial communication port connector, of the primary chassis management controller 126 is to be connected to a serial communication port connector of 264 of PDU B.

When a particular PDU 130 is installed in the rack-based computer system 110, the serial cable 272 is connected to the appropriate serial port of the primary chassis management controller 126 and allows the PDU 130 to assert a presence signal on the serial cable 272 to alert the primary chassis management controller 126-1 to the presence of the installed PDU 130. The primary chassis management controller 126 may then communicate over the serial cable 272 to retrieve FRU data from the PDU 130, including data representing the MAC address of the PDU 130 and other information about the PDU 130. The specific serial port connector to which the PDU 130 is connector allows the primary chassis management controller 126 to designate the PDU 130 as either PDU A or PDU B. In accordance with example implementations, the primary chassis management controller 126 may be connected by serial cabling to the CDU 134, such that the controller 126 may detect the presence of the CDU 134 and retrieve FRU from the CDU 134.

Cabling connection rules may specify how network cabling 270 (e.g., Ethernet cabling) is to be connected among the rack support units and the chassis management controllers 126. As depicted in FIG. 2, PDU A has a network port connector 260 (e.g., an Ethernet port connector) to be connected by a network cable 272 to a network port connector 212 of the network switch 124 of the secondary chassis management controller 126 that corresponds to chassis ID 2; and PDU B has a network port connector 260 to be connected by way of a network cable 272 to a network port connector 212 of the network switch 124 of the secondary chassis management controller 126 that corresponds to chassis ID 3. Moreover, as depicted in FIG. 2, the CDU 134 has a network port connector 280 that is to be connected by a network cable 272 to the network port connector 212 of the secondary chassis management controller 126 that corresponds to chassis ID 4.

As depicted in FIG. 2, in accordance with example implementations, each chassis management controller 126 may contain a network switch 124, a level two switch, which contains various ports, such as illustrated network ports 210 and 212, as well as, for example, one or additional network ports, such as, for example, a network port to connect the chassis management controller 126 to the ToR switch 119 (FIG. 1). The network switch 124,

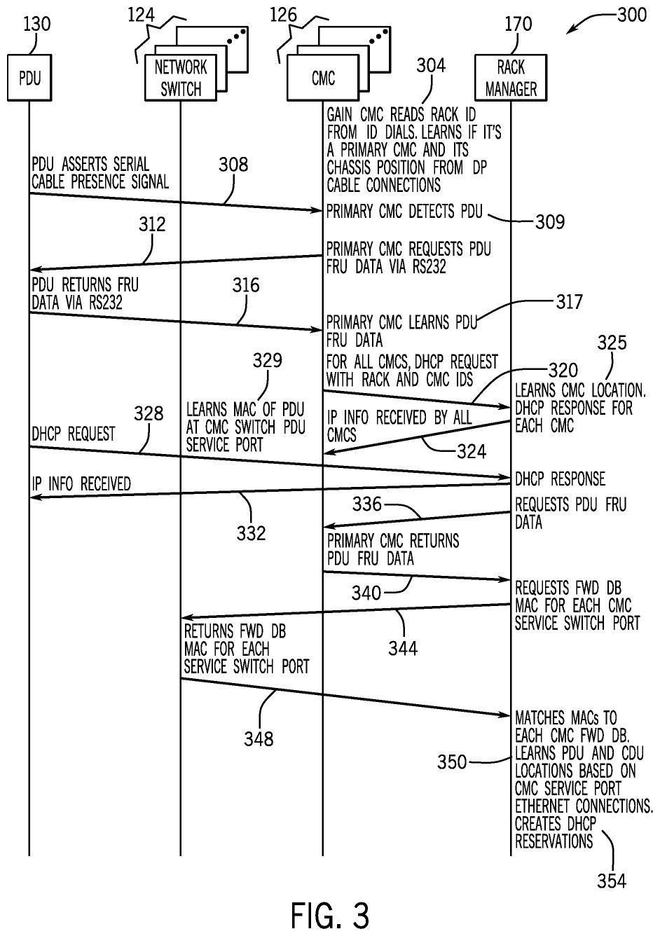

FIG. 3 depicts a signal flow 300 associated with an automated discovery process used by the rack manager 170 to discover information about a rack-based computer system 110, in accordance with example implementations. For this example implementation, information about network cabling between a rack support unit (for this example, a PDU 130) is obtained using forwarding table information obtained from the network switches 124 of the chassis management controllers 126. It is noted that FIG. 3 depicts the network switches 124 and the chassis management controllers 126 separately, with it being understood that the network switches 124 may be part of the chassis management controllers 126.

Referring to FIG. 3 in conjunction with FIGS. 1 and 2, in accordance with example implementations, the discovery process begins by each chassis management controller 126 reading (as depicted at reference numeral 304) its rack ID from its corresponding rack ID dial (e.g., an electromechanical dial whose position may be manipulated to set a particular ID). Moreover, each chassis management controller 126 may determine if it is the primary chassis management controller by the chassis ID and determine its position in the rack using the DP cable connections 230 (i.e., determine if the DP cable 230 is connected to its port connector 228, whether the DP cables are instead connected to its port connectors 216, 220 and 224, and so forth).

As depicted in FIG. 3, at reference numeral 308, the PDU 130 has been installed and asserts a serial cable presence signal (over the serial cable 272), which causes the primary chassis management controller 126 to detect the PDU 130, as depicted at 309. In response to the detection, the primary chassis management controller 126 requests (as depicted at 312) the FRU data from the PDU 130 via the serial connection, and the PDU 130 returns the FRU data, as depicted at 316. As such, the primary chassis management controller 126 learns the FRU data, i.e., learns the MAC address of the PDU 130 as well as other information about the PDU 130, as depicted at 317.

The chassis management controllers 126 issue DHCP requests, as depicted at 320, for purposes of acquiring IP addresses. These DHCP requests also include the rack and chassis IDs of the chassis management controllers 146 issuing the request. Therefore, from the DHCP requests from the chassis management controllers 126, the rack manager 170 may then associate the chassis management controllers 126 with particular racks and learn the location of the chassis management controllers 126 within the rack, as depicted at 325.

As depicted at 328, the PDU 130 also issues a DHCP request for purposes of obtaining an IP address. This DHCP request from the PDU 130 traverses a network switch 124 of a particular chassis management controller 126; and accordingly, this network switch 124 learns the MAC address of the PDU 130 (as depicted at 329) and populates its forwarding table with the MAC address-to-port association. The rack manager 170, if also serving as the DHCP server, may then respond to the DHCP request from the PDU 130 and provide the IP address to the PDU 130, as depicted at 332.

As part of the discovery process, the rack manager 170 requests (as depicted at 336) the PDU FRU data from the primary chassis management controller 126-1, and the primary chassis management controller 126-1 returns the PDU FRU data to the rack manager 170, as depicted at 340.

As depicted at reference numeral 334, in accordance with example implementations, the rack manager 170 may request (via an application programming interface (API) call, for example) the forwarding tables from the network switches 124, and accordingly, the switches 124 return data representing the forwarding tables, as depicted at reference numeral 348. The rack manager 170 may then match the MAC addresses from the discovered rack support units, such as the PDU 130, to the MAC addresses of the forwarding tables for purposes of learning the PDU and CDU locations based on the network connections to their respective chassis management controllers 126. As depicted at reference numeral 354, the rack manager 170 may then create DHCP reservations.

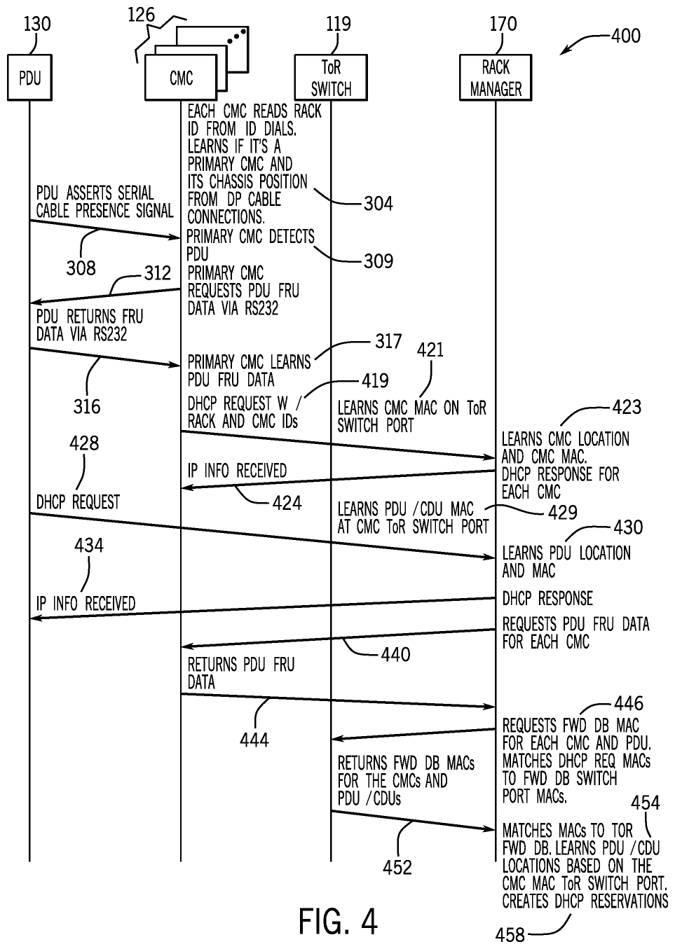

FIG. 4 illustrates a signal flow 400 associated with an automated discovery process that is performed by the rack manager 170 when the rack manager 170 uses the forwarding table of the ToR switch 119, instead of forwarding table information from the network switches 124 of the chassis management controllers 126. More specifically, referring to FIG. 4 in conjunction with FIGS. 1 and 2, the signal flow 400 contains several aspects similar to the signal flow 300, with like reference numerals being used to denote similar communications. As depicted at 419, each chassis management controller 126 issues a DHCP request containing its rack and chassis IDs, and each DHCP request traverses a port of the ToR switch 119. Accordingly, the ToR switch 119 learns the chassis management controller MAC address on the particular port that received the DHCP request. This information, in turn, is stored in the forwarding table of the ToR switch 119. As depicted at 423, the rack manager 170, for each DHCP request, learns the location of the chassis management controller 126 and its MAC address. The rack manager 170 may then, when functioning as a DHCP server, provide the IP address to the chassis management controller in response to the DHCP request, as depicted at 424.

The PDU 130 also issues a DHCP request, as depicted at 428, for purposes of obtaining an IP address, and this DHCP request traverses a port of the ToR switch 119. From this information, the ToR switch 119 may then learn the MAC address of the PDU 130, as depicted at 429. Moreover, as depicted at 430, from the DHCP request, the rack manager 170 learns the PDU location and the MAC address of the PDU. Moreover, as depicted at 434, the rack manger 170 responds to the PDU 130 with an IP address.

As depicted at 440, the rack manager 170 may then request PDU FRU data from the primary chassis management controller and receive, as depicted at 444, the PDU FRU data from the primary chassis management controller 126. The rack manager 170 may then request (as depicted at 446) the forwarding table from the ToR switch 119, and the ToR switch 119 may then return the forwarding table, as depicted at 452. The forwarding table, in turn, contains a port-to-MAC address mapping, showing the relationships between these chassis management controller MAC addresses and ports, and also showing the relationship between the PDU MAC address and particular port of the ToR switch 119. Therefore, the rack manager 170 may, through these mappings, associate the PDU 130 with a particular chassis management controller 126, as depicted at 454.

Although implementations are described herein in which MAC addresses are learned from DHCP requests, in accordance with further example implementations, the PDUs, CDUs and chassis management controllers may request IP addresses using DHCP version 6 (DHCPv6) requests, which contain unique identifiers, instead of MAC addresses, for the requesting clients. For these further example implementations, the forwarding tables contain port to unique identifier mappings, and the rack manager may use this information to associate rack support units with chassis management controllers. Both MAC addresses and DHCPv6 unique identifiers are considered herein to be “identifiers” for components derived from DHCP requests, such as, for example, identifiers for the rack support units.

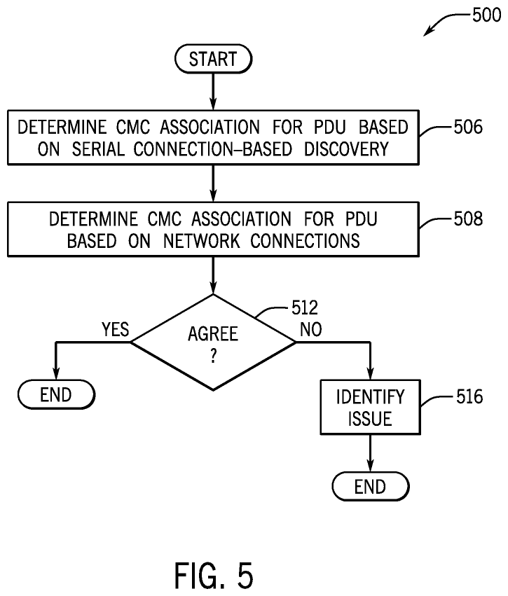

Referring to FIG. 5, thus, in accordance with example implementations, the rack manager 170 may perform a technique 500, which includes determining (block 506) chassis management controller associations for a PDU based on serial connection-based discovery and determine (diamond 508) chassis management controller association for the PDU based on network connections. If the rack manager 170 determines (decision block 512) that the two associations do not agree, then the rack manager 170 may then identify a potential network cabling and/or configuration problem, as depicted at block 516.

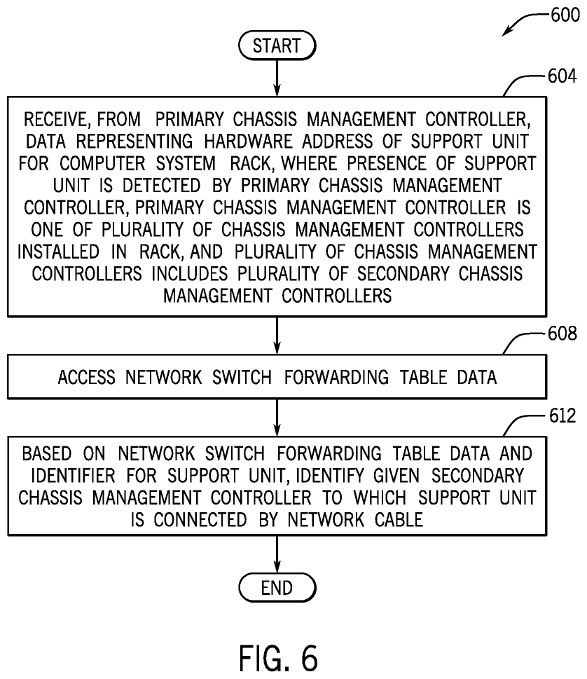

Referring to FIG. 6, in accordance with example implementations, a method 600 includes receiving (block 604) from a primary management controller, data representing an identifier for a support unit for a computer system rack. The presence of the support unit is detected by the primary chassis management controller, the primary chassis management controller is one of a plurality of chassis management controllers installed in the rack, and the plurality of chassis management controllers includes a plurality of secondary chassis management controllers. The technique 600 includes accessing (block 608) network switch forwarding table data; and, based on the network switch forwarding table data and the identifier for the support unit, identifying (block 612) a given secondary chassis management controller to which the support unit is connected by a network cable.

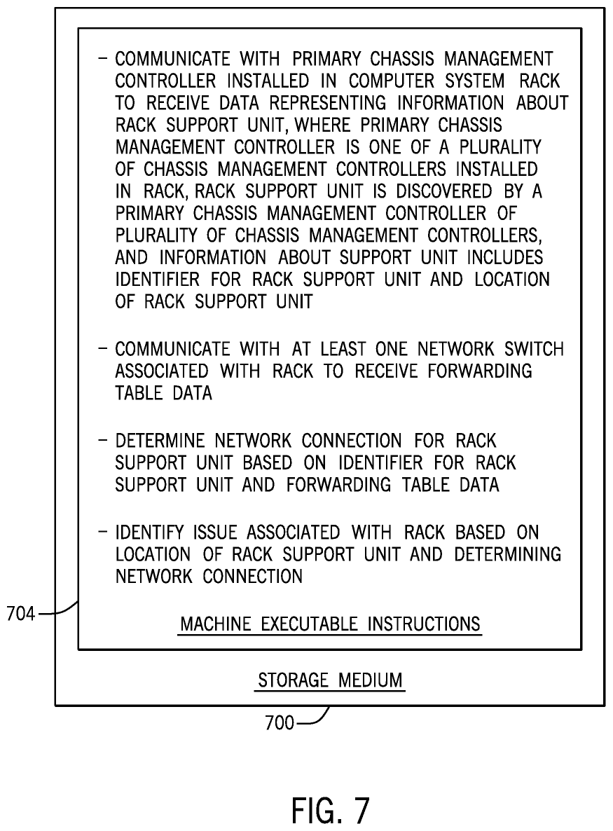

Referring to FIG. 7, in accordance with an example implementation, a non-transitory machine readable storage medium 700 stores instructions 704 that, when executed by a machine, cause the machine to communicate with a primary chassis management controller installed in a computer system rack to receive data representing information about a rack support unit. The primary chassis management controller is one of a plurality of chassis management controllers that are installed in the rack; the rack support unit is discovered by a primary chassis management controller of the plurality of chassis management controllers, and the information about the rack support unit includes an identifier for the rack support unit and an indicated location of the rack support unit. The instructions 704, when executed by the machine, further cause the machine to communicate with at least one network switch that is associated with the rack to receive forwarding table data; determine a network connection for the rack support unit based on the identifier for the rack support unit and the forwarding table data; and identify an issue that is associated with the rack based on the location of the rack support unit and the determined network connection based on the indicated location of the rack support unit and the determined network connection.

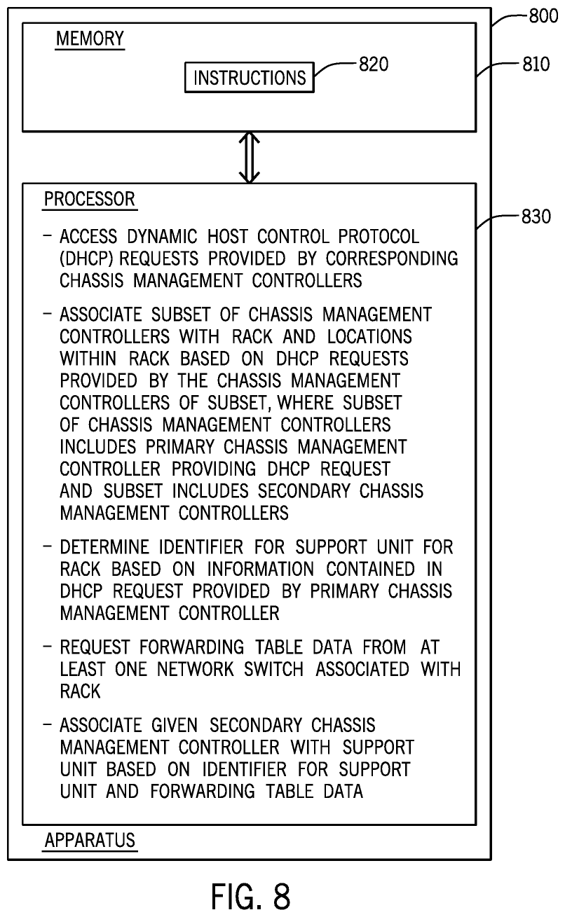

Referring to FIG. 8, in accordance with example implementations, an apparatus 800 includes at least one processor 830 and a memory 810. The memory 810 stores instructions 820 that, when executed by the processor(s) 830, cause the processor(s) 830 to access dynamic host protocol (DHCP) requests that are provided by corresponding chassis management controllers; associate a subset of the chassis management controllers with a rack and locations within the rack based on the DHCP requests that are provided by the chassis management controllers of the subset. The subset of chassis management controllers includes a primary chassis management controller providing a DHCP request and the subset of chassis management controllers includes a plurality of secondary chassis management controllers. The instructions 820 when executed by the processor(s) 830, further cause the processor(s) 830 to determine an identifier for a support unit for the rack based on information contained in the DHCP request provided by the primary chassis management controller; request forwarding table data from at least one network switch that is associated with the rack; and associate a given secondary chassis management controller with the support unit based on the identifier for the support unit and the forwarding table data.

In accordance with an example implementation, a DHCP request is received from the support unit, where the DHCP request is communicated through a port of a plurality of ports of a network switch corresponding to the given secondary chassis management controller. A particular advantage of the DHCP request from the support unit is that the network switch maps and association between an identifier for the support unit and the port of the network switch.

In accordance with an example implementation, a plurality of DHCP requests for IP addresses are received from a plurality of chassis management controllers, where each chassis management controller of the plurality is associated with a chassis of a plurality of chassis mounted to the rack; and each DHCP request is associated with a different chassis management controller and contains data representing a chassis location identifier for the associated chassis management controller. A particular advantage of this arrangement is that the chassis management controllers may be associated with a location in the rack.

In accordance with example implementations, each DHCP request may include data representing a rack identifier. A particular advantage of this arrangement is that the chassis management controllers may be associated with a particular rack.

In accordance with example implementations, the support unit is associated with a chassis location identifier associated with the given secondary chassis management controller. A particular advantage of this association is that configuration and/or cabling errors may be detected.

In accordance with an example implementation, the forwarding table includes a port-to-identifier mapping, and identifying the given secondary chassis management controller includes using the identifier for the support unit as an index to the mapping to identify a port of the network switch corresponding to the given secondary chassis management controller. A particular advantage of this association is that configuration and/or cabling errors may be detected.

In accordance with example implementations, accessing the network switch forwarding table data includes requesting forwarding table data stored in a plurality of network switches that are located in the chassis management controllers. A particular advantage of this association is that configuration and/or cabling errors may be detected.

In accordance with example implementations, accessing the network switch forwarding table data includes requesting forwarding table data that is stored in a top-of-the-rack (ToR) network switch that has a separate network cable in connection to each chassis management controller of the chassis management controllers. A particular advantage of this arrangement is that it may be easier to request the forwarding table data from a single network switch.

While the present disclosure has been described with respect to a limited number of implementations, those skilled in the art, having the benefit of this disclosure, will appreciate numerous modifications and variations therefrom. It is intended that the appended claims cover all such modifications and variations.

1. A method comprising:
receiving, from a primary chassis management controller, data representing an identifier of a support unit for a computer system rack, wherein presence of the support unit is detected by the primary chassis management controller, the primary chassis management controller is one of a plurality of chassis management controllers installed in the rack, and the plurality of chassis management controllers comprises a plurality of secondary chassis management controllers;
accessing a network switch to retrieve forwarding table data including network cabling information, wherein the network cabling information includes information indicating the plurality of secondary chassis management controllers and a plurality of support units coupled to the primary chassis management controller via ports of the switch; and
based on the network cabling information and the identifier for the support unit, identifying a given secondary chassis management controller of the plurality of secondary chassis management controllers to which the support unit is connected by a network cable.

2. The method of claim 1, further comprising:
receiving, from the support unit, a dynamic host control protocol (DHCP) request for an internet protocol (IP) address for the support device, wherein the DHCP request is communicated through a port of a plurality of ports of a network switch corresponding to the given secondary chassis management controller.

3. The method of claim 1, further comprising:
receiving, from the plurality of chassis management controllers, a plurality of dynamic host control protocol (DHCP) requests for internet protocol (IP) addresses, wherein each chassis management controller of the plurality of chassis management controllers is associated with a chassis of a plurality of chassis mounted to the rack, and each DHCP request of the plurality of DCHP requests is associated with a different chassis management controller of the plurality of chassis management controllers and contains data representing a chassis location identifier for the associated chassis management controller.

4. The method of claim 3, wherein said each DHCP request further comprises data representing a rack identifier.

5. The method of claim 3, further comprising associating the support unit with the chassis location identifier associated with the given secondary chassis management controller.

6. The method of claim 1, wherein the forwarding table of the network switch comprises a port-to-identifier mapping, and identifying the given secondary chassis management controller comprises using the identifier for the support unit as an index to the mapping to identify a port of a network switch corresponding to the given secondary chassis management controller.

7. The method of claim 1, wherein accessing the network switch forwarding table data comprises:
requesting forwarding table data stored in a plurality of network switches located in the plurality of chassis management controllers.

8. The method of claim 1, wherein accessing the network switch forwarding table data comprises:
requesting the network cabling information included in the forwarding table data stored in the network switch having a separate network cabling connection to each chassis management controller of the plurality of chassis management controllers.

9. The method of claim 1, wherein the support unit is connected to a serial communication port of a given chassis management controller of the plurality of chassis management controllers, wherein the serial communication port is associated with a chassis identifier, the method further comprising:
receiving, from the given chassis management controller, data representing an identity of the serial communication port;
comparing the chassis identifier to a chassis identifier associated with the given secondary chassis management controller; and
identifying at least one of a network cabling connection problem or a configuration problem based on a result of the comparison.

10. The method of claim 1, wherein the support unit comprises a power distribution unit for the rack or a cooling distribution unit for the rack, and wherein the cooling distribution unit comprises a water-to-water heat exchanger or an air-to-water heat exchanger unit.

11. A non-transitory machine readable storage medium that stores instructions that, when executed by a machine, cause the machine to:
communicate with a primary chassis management controller installed in a computer system rack to receive data representing information about a rack support unit, wherein the primary chassis management controller is one of a plurality of chassis management controllers installed in the rack, the rack support unit is discovered by a primary chassis management controller of the plurality of chassis management controllers, and the information about the rack support unit comprises an identifier for the rack support unit and an indicated location of the rack support unit;
communicate with at least one network switch associated with the rack to receive forwarding table data including network cabling information, wherein the network cabling information includes information indicating the plurality of secondary chassis management controllers and a plurality of support units coupled to the primary chassis management controller via ports of the switch;
determine a network connection for the rack support unit based on the identifier for the rack support unit and the network cabling information; and
identify an issue associated with the rack based on the indicated location of the rack support unit and the determined network connection.

12. The storage medium of claim 11, wherein the instructions further cause the machine to identify a cabling or configuration problem with the rack based on the comparison.

13. The storage medium of claim 11, wherein the instructions further cause the machine to communicate with a plurality of network switches of the plurality of chassis management controllers to receive the forwarding table data.

14. The storage medium of claim 11, wherein the instructions further cause the machine to communicate with a top of the rack (ToR) network switch associated with the rack to receive the forwarding table data.

15. The storage medium of claim 11, wherein the plurality of chassis management controllers comprises a plurality of secondary chassis management controllers, and the forwarding table data associates the identifier for the rack support unit with a port of a given secondary chassis management controller of the plurality of secondary chassis management controllers.

16. An apparatus comprising:
at least one processor; and
a memory to store instructions that, when executed by said at least one processor, cause said at least one processor to:
access dynamic host control protocol (DHCP) requests provided by corresponding chassis management controllers of a plurality of chassis management controllers;
associate a subset of chassis management controllers of the plurality of chassis management controllers with a rack and locations within the rack based on the DHCP requests provided by the chassis management controllers of the subset of chassis management controllers, wherein the subset of chassis management controllers comprises a primary chassis management controller providing a DHCP request of the DHCP requests and the subset of chassis management controllers comprises a plurality of secondary chassis management controllers;
determine an identifier for the support unit for the rack based on information contained in the DHCP request provided by the primary chassis management controller;
request forwarding table data including network cabling information from at least one network switch associated with the rack, wherein the network cabling information includes information indicating the plurality of secondary chassis management controllers and a plurality of support units coupled to the primary chassis management controller via ports of the switch; and
associate a given secondary chassis management controller of the plurality of secondary chassis management controllers with the support unit based on the identifier for the support unit and the network cabling information.

17. The apparatus of claim 16, wherein the DHCP requests comprise data representing rack identifiers and chassis location identifiers for the plurality of chassis management controllers.

18. The apparatus of claim 16, wherein the instructions, when executed by said at least one processor, cause said at least one processor to request the forwarding table data from a top of the rack (ToR) network switch coupled by network cabling to the chassis management controllers of the subset of chassis management controllers.

19. The apparatus of claim 16, wherein the forwarding table comprises a mapping between the identifier for the support unit and a one or more ports of the network switch associated with the identifie.

20. The apparatus of claim 16, wherein:
the primary chassis management controller discovers the support unit;
the DHCP request provided by the primary chassis management controller represents a location of the support unit; and
the instructions, when executed by said at least one processor, further cause said at least one processor to identify an issue associated with the rack based on the association of the given secondary chassis management controller with the support unit and the location.
